(19) United States
(12) Patent Application Publication
(10) Pub. No.: US 2026/0181792 A1
(43) Pub. Date: Jun. 25, 2026

(54) VIBRATION DAMPING DEVICE AND ELECTRONIC APPARATUS HAVING THE SAME

(71) Applicant: INDUSTRIAL TECHNOLOGY RESEARCH INSTITUTE, Hsinchu (TW)

(72) Inventors: Pin-Jen Chen, Yunlin County (TW); Chien-Chih Liao, Taichung City (TW); Hsiao-Chen Ho, Taichung City (TW); Jheng-Jie Lin, Taichung City (TW)

(73) Assignee: INDUSTRIAL TECHNOLOGY RESEARCH INSTITUTE, Hsinchu (TW)

(21) Appl. No.: 19/000,897

(22) Filed: Dec. 24, 2024

(51) Int. Cl. H05K 5/00; F16F 7/116

(52) U.S. Cl. CPC H05K 5/0056; F16F 7/116

(57) ABSTRACT

A vibration damping device and an electronic apparatus having the vibration damping device are provided. The vibration damping device includes a fixed base, a flexible member, and a mass block. The flexible member is arranged on the fixed base, and the flexible member includes a plurality of damping arms having a plurality of concave notches. The mass block is disposed on the at least one damping arm. A ratio of a stiffness of the flexible member to a mass of the mass block is between 1.5×10⁶ to 4×10⁷. The electronic apparatus includes a circuit board and a vibration damping device, and the vibration damping device is mounted on the circuit board.

### TECHNICAL FIELD

The instant disclosure is related to a vibration damping device and an electronic apparatus having the same.

### BACKGROUND

As to nowadays electronic apparatuses, vibration is a common external or internal interference source which will cause adverse effects on the stability and reliability of the apparatuses. For example, an electronic control unit (ECU) installed in a vehicle is subjected to high-frequency vibrations caused by road bumps or engine operation during vehicle movement. These vibrations may cause solder joints on the circuit board to loosen or result in poor contact, thereby affecting the normal operation of the device.

In the fields of aviation and aerospace, satellites and avionics equipment are often exposed to more extreme vibration environments. For instance, during rocket launches, satellite equipment is subjected to intense high-frequency thrust vibrations, while aerodynamic noise during flight can also cause interference. Such high-frequency vibrations may not only cause structural damage to electronic components but also reduce the reliability of the equipment, potentially leading to the failure of the entire mission.

Additionally, portable electronic devices such as smartphones, tablets, or laptops may be subjected to mechanical vibrations caused by drops, impacts, or shaking during daily use. These vibrations can further result in damage to internal precision components, thereby shortening the device's lifespan and degrading its performance.

To address the aforementioned issues caused by vibrations, some existing technologies have attempted to implement various vibration suppression devices, such as rubber pads, spring structures, or viscoelastic materials. However, these solutions often exhibit limited effectiveness or involve complex structural designs when dealing with diverse and extreme vibration environments. For instance, in high-temperature or low-temperature conditions, traditional damping materials may underperform, experience fatigue, or even fail entirely. Therefore, how to provide a new vibration damping device which can be coped with the vibration more effectively thereby improving the overall stability and reliability of the electronic apparatus becomes an issue to the inventor.

### SUMMARY

To address the issues mentioned above thoroughly, some embodiments of the instant disclosure provide a vibration damping device and an electronic apparatus having the vibration damping device. The proposed solution effectively suppresses vibrations, thereby extending the service life, as well as enhancing the overall stability and reliability of the electronic device.

One embodiment of the instant disclosure provides a vibration damping device, in which the vibration damping device mainly comprises a fixed base, a flexible member, and a mass block. The flexible member is arranged on the fixed base, and the flexible member comprises at least one damping arm having at least one concave notch. The mass block is disposed on the at least one damping arm. A ratio of a stiffness of the flexible member to a mass of the mass block is between 1.5×10⁶ to 4×10⁷.

One embodiment of the instant disclosure provides an electronic apparatus, in which the electronic apparatus comprises a circuit board and a vibration damping device. The vibration damping device is mounted on the circuit board and comprises a fixed base, a flexible member, and a mass block. The flexible member is arranged on the fixed base and comprises at least one damping arm having at least one concave notch. The mass block is disposed on the at least one damping arm. A ratio of a stiffness of the flexible member to a mass of the mass block is between 1.5×10⁶ to 4×10⁷.

As above, according to some embodiments of the instant disclosure, the vibration damping device and the electronic apparatus having the same can significantly enhance the ability to isolate and suppress vibrations.

### BRIEF DESCRIPTION OF THE DRAWINGS

The disclosure will become more fully understood from the detailed description given herein below for illustration only, and thus not limitative of the disclosure, wherein:

FIG. 1A illustrates a perspective view of a vibration damping device according to an exemplary embodiment of the instant disclosure, wherein an upper cover of the vibration damping device is not shown;

FIG. 1B illustrates a cross-sectional view of FIG. 1A;

FIG. 1C illustrates an exploded view of the vibration damping device according to an exemplary embodiment of the instant disclosure;

FIG. 2A illustrates a perspective view of a flexible member of the vibration damping device, wherein the flexible member is a cross-shaped damping arm, and the concave notch of the flexible member is a semicircle groove;

FIG. 2B illustrates an enlarged partial perspective view of the damping arm of the vibration damping device according to an exemplary embodiment of the instant disclosure;

FIG. 3 illustrates a graph showing the relationship between frequency and vibration level of the vibration damping device according to an exemplary embodiment of the instant disclosure;

FIG. 4A illustrates a perspective view of the flexible member of the vibration damping device according to another exemplary embodiment of the instant disclosure, wherein the flexible member is a single damping arm, and the concave notch is a semicircle groove;

FIG. 4B illustrates a perspective view of the flexible member of the vibration damping device according to another exemplary embodiment of the instant disclosure, wherein the flexible member is a single damping arm, and the concave notch is a V-shaped groove;

FIG. 4C illustrates a perspective view of the flexible member of the vibration damping device according to another exemplary embodiment of the instant disclosure, wherein the flexible member is a single damping arm, and the concave notch is an ellipse groove;

FIG. 4D illustrates a perspective view of the flexible member of the vibration damping device according to another exemplary embodiment of the instant disclosure, wherein the flexible member is a single damping arm, and the concave notch is a rectangle groove;

FIG. 5 illustrates a perspective view of the flexible member of the vibration damping device according to yet another exemplary embodiment of the instant disclosure, wherein the flexible member is a tri-branch shape damping arm, and the concave notch is a semicircle groove;

FIG. 6 illustrates a perspective view of the flexible member of the vibration damping device according to still yet another exemplary embodiment of the instant disclosure, wherein the flexible member is a union jack-like shape damping arm, and the concave notch is a semicircle groove; and

FIG. 7 illustrates a perspective view of an electronic apparatus according to an exemplary embodiment of the instant disclosure.

### DETAILED DESCRIPTION

Embodiments are provided for facilitating the descriptions of the instant disclosure. However, the embodiments are provided as examples for illustrative purpose, but not limitations to the instant disclosure. Moreover, in the figures, some components are omitted to show the technical features of the instant disclosure clearly. Furthermore, in all the figures, the same reference numbers refer to identical or similar elements. Besides, the figures in the instant disclosure are provided merely for illustrative purposes and may not necessarily be drawn to scale, and not all the details of the instant disclosure may be shown in the figures.

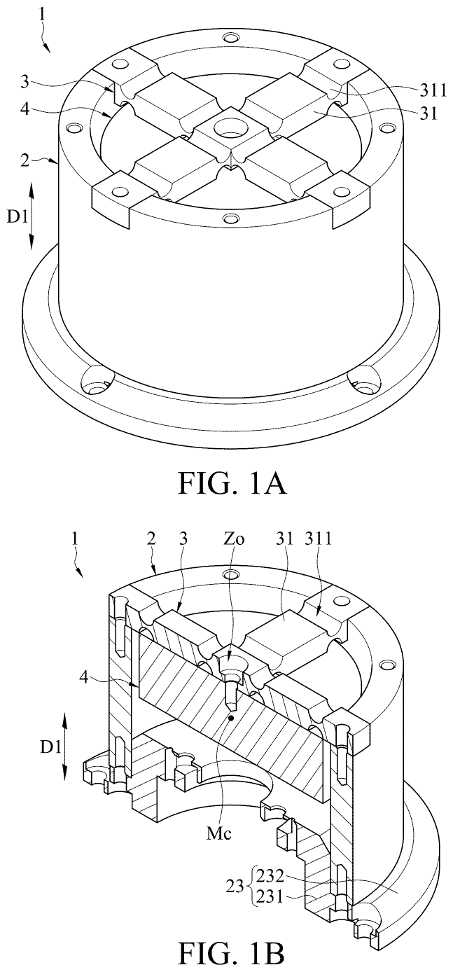

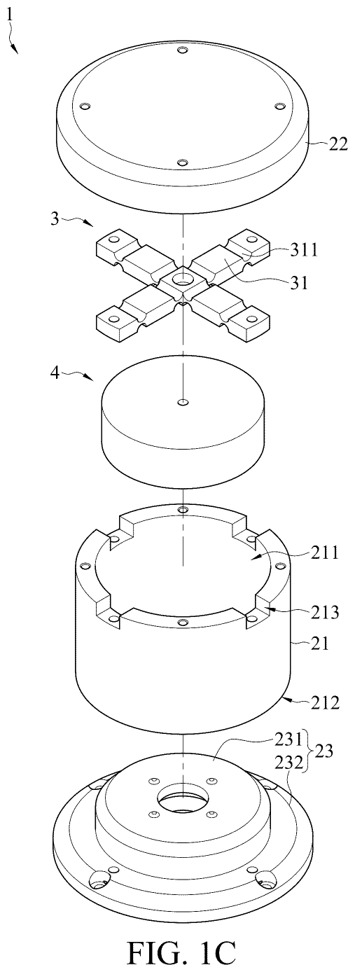

Please refer to FIG. 1A, FIG. 1B, and FIG. 1C. FIG. 1A illustrates a perspective view of a vibration damping device 1 according to an exemplary embodiment of the instant disclosure, wherein an upper cover 22 of the vibration damping device 1 is not shown. FIG. 1B illustrates a cross-sectional view of FIG. 1A. FIG. 1C illustrates an exploded view of the vibration damping device 1 according to an exemplary embodiment of the instant disclosure. As shown, the vibration damping device 1 mainly comprises a fixed base 2, a flexible member 3, and a mass block 4. The flexible member 3 is arranged on the fixed base 2 and has at least one damping arm 31, and the damping arm 31 has at least one concave notch 311. The mass block 4 is attached on the damping arm 31. A ratio of a stiffness of the flexible member 3 to a mass of the mass block 4 is between 1.5×10⁶ to 4×10⁷.

In some embodiments, the damping arm 31 includes a plurality of concave notches 311, with the notch directions of the concave notches 311 are oriented in a direction aligned with the first direction. This first direction D1 corresponds to the axial direction of the hollow cylindrical body 21. The fixed base 2 comprises a hollow cylindrical body 21, an upper cover 22, and a lower base 23. The damping arm 31 spans across the hollow cylindrical body 21, and the mass block 4 is accommodated within the hollow cylindrical body 21. The mass block 4 does not interfere with the hollow cylindrical body 21, so that the mass block 4 is movable along an axial direction of the hollow cylindrical body 21 (along a first direction D1). The upper cover 22 and the lower base 23 are respectively at openings of two ends of the hollow cylindrical body 21 to seal the openings at the two ends.

The hollow cylindrical body 21 has a first opening end 211 and a second opening end 212. The upper cover 22 is assembled on the first opening end 211, and the lower base 23 is assembled on the second opening end 212. The first opening end 211 comprises a plurality of mounting slots 213, and two ends of the damping arm 31 are respectively mounted on the mounting slots 213. Moreover, the lower base 23 comprises an axial projection 231 and a radial flange 232, the axial projection 231 is in the hollow cylindrical body 21, and the radial flange 232 extends outwards from the second end opening 212 of the hollow cylindrical body 21.

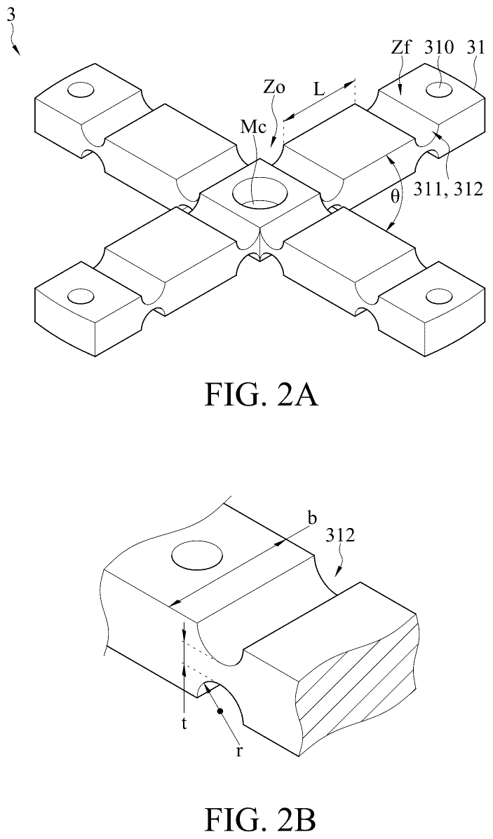

Please refer to FIG. 2A. FIG. 2A illustrates a perspective view of a flexible member 3 of the vibration damping device 1, wherein the flexible member 3 is a cross-shaped damping arm 310, and the concave notch 311 of the flexible member 3 is a semicircle groove 312. In some other embodiments, the concave notch 311 is not limited to the semicircle groove 312 but may also be an ellipse groove, a rounded rectangle groove, a stadium-shaped groove, or other geometric polygon grooves.

In some embodiments, the flexible member 3 comprises a plurality of damping arms 31, and the flexible member 3 has a centroid Mc. The damping arms 31 takes the centroid Mc as a center of circle, and a central angle θ between each pair of adjacent damping arms 31 is equal. In other words, all the damping arms 31 are radially arranged at equal angles around the centroid Mc, which helps ensure that each damping arm 31 bears the same stress and undergoes the same strain.

In the embodiment shown in FIG. 2A, the flexible member 3 comprises two damping arms 31, each of the two damping arms 31 has a centroid, and the two damping arms 31 are orthogonal to each other. The centroids of the two damping arms 31 coincide, so that the two damping arms 31 form a cross-shaped damping arm 310. Moreover, the damping arms 31 comprise an overlapped region Zo and a plurality of fixed regions Zf. The overlapped region Zo is the portions where the two orthogonal damping arms 31 intersect. The fixing regions Zf are located at opposite ends of the damping arms 31 and are used to connect to the fixing base 2, specifically the portions where the damping arms 31 overlap with the hollow tubular body 21.

In some embodiments, each damping arm 31 is provided with multiple recessed notches 311. These recessed notches 311 are arranged in pairs on the upper and lower corresponding surfaces of the damping arm 31, and they are positioned near the overlapping region Zo and the fixing regions Zf. Specifically, as shown in FIG. 2A, each damping arm 31 includes four recessed notches 311. These recessed notches 311 are symmetrically distributed in pairs on the upper and lower surfaces of the damping arm 31, with each pair located adjacent to the overlapping region Zo and the fixing regions Zf. It should be noted that the arrangement of the recessed notches 311 is not limited to being paired on the upper and lower surfaces of the damping arm 31 and can be adjusted according to practical application needs.

As shown in FIG. 1A, FIG. 1B, and FIG. 1C, the mass block 4 is arranged on the overlapped region Zo. In some embodiments, the damping arms 31 and the mass block 4 each have a respective centroid Mc. These centroids Mc are all located on a centerline of the hollow cylindrical body 21. Therefore, when the vibration damping device 1 operates, namely when the lower base 23 receives the vibration energy, the vibration energy will be transmitted to the damping arm 31 through the hollow cylindrical body 21. This causes the mass block 4 to produce an amplitude (displacement) along the first direction D1. In other words, the vibration suppression device 1 can effectively suppress vibration in the first direction D1, which is perpendicular to the mounting surface of the vibration suppression device 1.

Please refer to FIG. 2B. FIG. 2B illustrates an enlarged partial perspective view of the damping arm 31 of the vibration damping device 1 according to an exemplary embodiment of the instant disclosure. In the embodiment shown in FIG. 2B, the concave notch 311 is a semicircle groove 312; a length b of the semicircle groove 312 is greater than a radius r of the semicircle groove 312, and the radius r of the semicircle groove 312 is greater than a thickness t between two semicircle grooves 312 at the two opposing surfaces of the damping arm 31.

In some embodiments, the flexible member 3 may be made of metallic material, and the stiffness of the flexible member 3 is equal to or greater than 60 GPa. For example, the flexible member 3 for example may be made of, but not limited to, aluminum (having a stiffness of about 70 GPa), cast iron (having a stiffness of about 100-120 GPa), copper (having a stiffness of about 120 GPa), wrought iron (having a stiffness of about 190 GPa), or steel (having a stiffness of about 200 GPa). Additionally, in certain embodiments, the vibration suppression device 1 can suppress more than 20% of high-frequency vibrations with a frequency range between 200 Hz and 1000 Hz. In general, the vibration suppression device 1 can suppress at least 50% to 60% of the vibration amplitude.

In some embodiments, the weight of the mass block 4 is approximately 200 grams. However, this parameter is not limiting. Depending on the scale of the damper or the vibration frequency to be addressed, the weight of the mass block 4 and the overall stiffness of the flexible element 3 can be adjusted accordingly. The ratio of the stiffness of the flexible member 3 to the mass of the mass block 4 is suggested between 1.5×10⁶ to 4×10⁷.

The following will demonstrate the damping effect of each embodiment using computer simulation data. In the embodiment shown in FIG. 2A and FIG. 2B, the parameters of the damping arm 31 include: the length b of the semicircle groove 312 is 10 mm; the radius r of the semicircle groove 312 is 2 mm; the thickness t between the two semicircle grooves 312 at the two opposing surfaces of the damping arm 31 is 1.5 mm; the overall thickness of the damping arm 31 is 5.5 mm; along the length direction of the damping arm 31, the distance L between two semicircle grooves 312 is 12 mm.

Moreover, in this embodiment specifically applied for computer simulations, the flexible member 3 is made of aluminum, with the following relevant parameters: the stress concentration factor is 0.58975, the shape factor is 1.1735714, the torsional stiffness is 5.7×10⁵, and the overall stiffness is 2.85×10⁶ N/m.

On the other hand, the relevant parameters of the mass block 4 are as follows: the diameter of the mass block 4 is 50 mm, the height of the mass block 4 is approximately 14 mm, and the weight of the mass block 4 is about 0.223 kg. In this embodiment, the ratio of the stiffness (N/m) of the flexible member 3 to the mass (kg) of the mass block 4 is 1.425×10⁷.

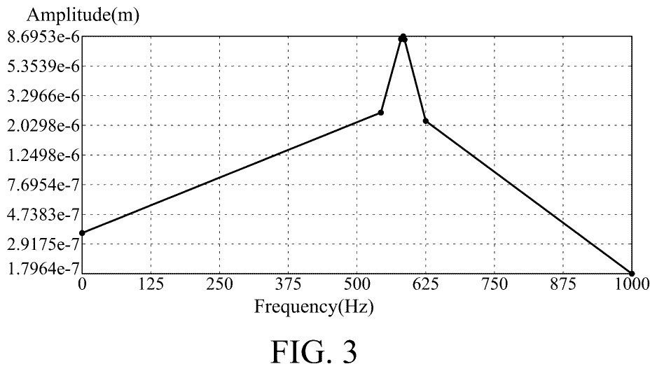

Please refer to FIG. 3. FIG. 3 illustrates a graph showing the relationship between frequency and vibration level (Amplitude) of the vibration damping device 1 according to an exemplary embodiment of the instant disclosure. As realized from FIG. 3, in the low frequency section (from 0 Hz to approximately 500 Hz), the magnitude of vibration level (Amplitude) gradually increases with the frequency. At around 569.6 Hz, the magnitude of vibration level (Amplitude) reaches the peak value, indicating that this frequency is the resonance frequency (natural frequency) or the frequency of maximum response the vibration damping device 1. This reflects the enhancement of the device's response at this frequency. Beyond 569.6 Hz, the magnitude of vibration level (Amplitude) gradually decreases with the increase in frequency, until it reaches 1000 Hz. In other words, through the aforementioned parameter settings, the vibration suppression device 1 exhibits the best vibration suppression effect around 569.6 Hz (natural frequency), significantly reducing the vibration magnitude near this frequency.

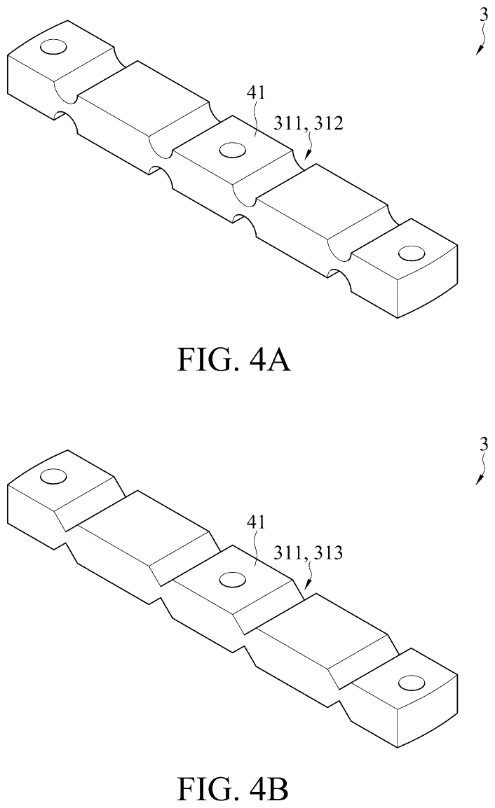

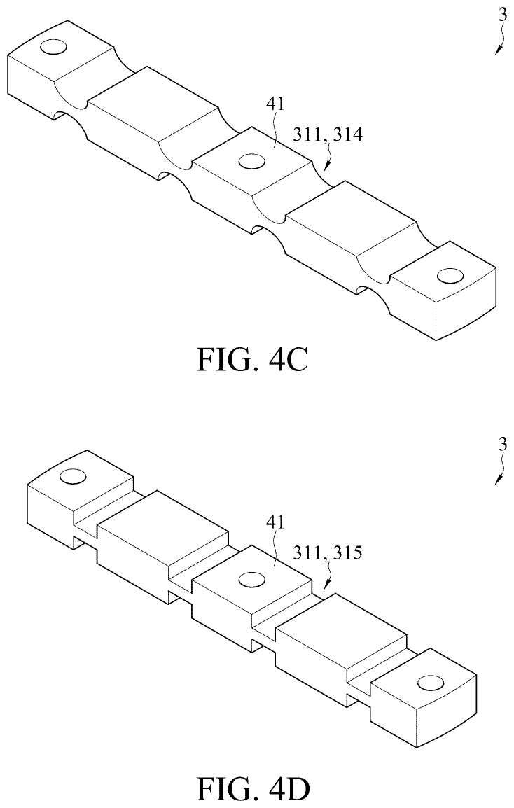

Below, effects of the shapes of the concave notch 311 on the vibration damping performance are discussed. Please refer to FIG. 4A, FIG. 4B, FIG. 4C, and FIG. 4D. FIG. 4A illustrates a perspective view of the flexible member 3 of the vibration damping device 1 according to another exemplary embodiment of the instant disclosure, wherein the flexible member 3 is a single damping arm, and the concave notch 311 is a semicircle groove 312. FIG. 4B illustrates a perspective view of the flexible member 3 of the vibration damping device 1 according to another exemplary embodiment of the instant disclosure, wherein the flexible member 3 is a single damping arm, and the concave notch 311 is a V-shaped groove 313. FIG. 4C illustrates a perspective view of the flexible member 3 of the vibration damping device 1 according to another exemplary embodiment of the instant disclosure, wherein the flexible member 3 is a single damping arm, and the concave notch 311 is an ellipse groove 314. FIG. 4D illustrates a perspective view of the flexible member 3 of the vibration damping device 1 according to another exemplary embodiment of the instant disclosure, wherein the flexible member 3 is a single damping arm, and the concave notch 311 is a rectangle groove 315.

In the embodiment shown in FIG. 4A, the parameters of the damping arm 41 are identical to the parameters of the damping arm 31 of FIG. 2A, and the difference between these embodiments lies in that, in this embodiment, the flexible member 3 is a single damping arm 41, while the flexible member 3 of the embodiment shown in FIG. 2A is the cross-shaped damping arm 310. According to the results of computer simulation, in this embodiment, the natural frequency of the single damping arm 41 is approximately 400 Hz, the overall stiffness of the single damping arm 41 is about 1279214 N/m, and the weight of the mass block 4 (please refer to FIG. 1A to FIG. 1C) is about 0.203 kg. In this embodiment, the ratio of the stiffness (N/m) of the flexible member 3 to the mass (kg) of the mass block 4 is 6.3×10⁶.

In the embodiment shown in FIG. 4B, the concave notch 311 is a V-shaped groove 313, and the angle of the V-shaped groove 313 is 45 degrees; other parameters of the single damping arm 41 are identical to the parameters of the damping arm 31 of FIG. 2A. According to result of the computer simulation, in this embodiment, the natural frequency of the single damping arm 41 is approximately 528 Hz, the overall stiffness of the single damping arm 41 is about 2243762 N/m, and the weight of the mass block 4 (please refer to FIG. 1A to FIG. 1C) is about 0.203 kg. In this embodiment, the ratio of the stiffness (N/m) of the flexible member 3 to the mass (kg) of the mass block 4 is 11×10⁶.

In the embodiment shown in FIG. 4C, the concave notch 311 is an ellipse groove 314, and a width of the ellipse groove 314 is 5 mm; other parameters of the single damping arm 41 are identical to the parameters of the damping arm 31 of FIG. 2A. According to result of the computer simulation, in this embodiment, the natural frequency of the single damping arm 31 is approximately 391 Hz, the overall stiffness of the single damping arm 31 is about 1228380 N/m, and the weight of the mass block 4 (please refer to FIG. 1A to FIG. 1C) is about 0.203 kg. In this embodiment, the ratio of the stiffness (N/m) of the flexible member 3 to the mass (kg) of the mass block 4 is 6.05×10⁶.

In the embodiment shown in FIG. 4D, the concave notch 311 is a rectangle groove 315, and a width of the rectangle groove 315 is 4 mm; other parameters of the single damping arm 41 are identical to the parameters of the damping arm 31 of FIG. 2A. According to result of the computer simulation, in this embodiment, the natural frequency of the single damping arm 31 is about 280 Hz, the overall stiffness of the single damping arm 31 is about 625939 N/m, and the weight of the mass block 4 (please refer to FIG. 1A to FIG. 1C) is about 0.203 kg. In this embodiment, the ratio of the stiffness (N/m) of the flexible member 3 to the mass (kg) of the mass block 4 is 3.08×10⁶.

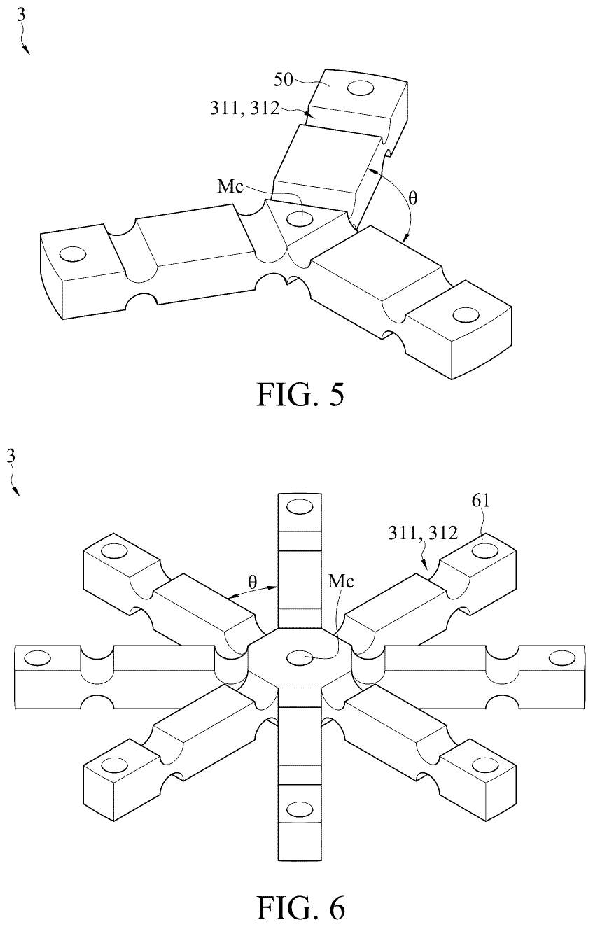

Please refer to FIG. 5. FIG. 5 illustrates a perspective view of the flexible member 3 of the vibration damping device 1 according to yet another exemplary embodiment of the instant disclosure, wherein the flexible member 3 is a tri-branch shape damping arm 50, and the concave notch 311 is a semicircle groove 312. In the embodiment shown in FIG. 5, the parameters of the flexible member 3 are identical to the parameters of the flexible member 3 of FIG. 2A, and the difference between these embodiments lies in that, in this embodiment, the flexible member 3 is a tri-branch shape damping arm 50, while the flexible member 3 of the embodiment shown in FIG. 2A is the cross-shaped damping arm 310. According to result of the computer simulation, in this embodiment, the natural frequency of the tri-branch shape damping arm 50 is about 491 Hz, the overall stiffness of the tri-branch shape damping arm 50 is about 1940880 N/m, and the weight of the mass block 4 (please refer to FIG. 1A to FIG. 1C) is about 0.204 kg. In this embodiment, the ratio of the stiffness (N/m) of the flexible member 3 to the mass (kg) of the mass block 4 is 9.5×10⁶.

Please refer to FIG. 6. FIG. 6 illustrates a perspective view of the flexible member 3 of the vibration damping device 1 according to still yet another exemplary embodiment of the instant disclosure, wherein the flexible member 3 is a union jack-like shape damping arm 61, and the concave notch 311 is a semicircle groove 312. In the embodiment shown in FIG. 6, the parameters of the flexible member 3 are identical to the parameters of the flexible member 3 of FIG. 2A, and the difference between these embodiments lies in that, in this embodiment, the flexible member 3 is union jack-like shape damping arm 61, while the flexible member 3 of the embodiment shown in FIG. 2A is the cross-shaped damping arm 310. According to result of the computer simulation, in this embodiment, the natural frequency of the union jack-like shape damping arm 61 is about 565 Hz, the overall stiffness of the union jack-like shape damping arm 61 is about 2616500 N/m, and the weight of the mass block 4 (please refer to FIG. 1A to FIG. 1C) is about 0.207 kg. In this embodiment, the ratio of the stiffness (N/m) of the flexible member 3 to the mass (kg) of the mass block 4 is 1.264×10⁷.

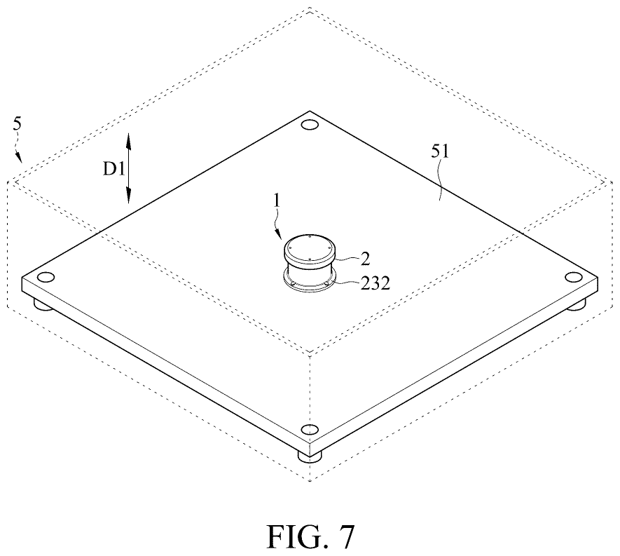

Please refer to FIG. 7. FIG. 7 illustrates a perspective view of an electronic apparatus 5 according to an exemplary embodiment of the instant disclosure. In the embodiment shown in FIG. 7, the vibration damping device 1 is mounted on a circuit board 51 It can be attached using fasteners (such as screws) that pass through the through-hole on the radial flange 232 and are secured to the circuit board 51. Alternatively, depending on the specific application, the vibration damping device 1 can be bonded to the circuit board 51 using adhesive. Additionally, under normal circumstances, the central position of the circuit board 51 is the location where the vibration is most intense. Therefore, the vibration damping device 1 can be installed at the center of the circuit board 51, effectively absorbing the vibrational energy.

In other embodiments, the vibration damping device 1 can be installed in the area where the vibration is most pronounced, typically near the resonance point caused by the natural frequency of the circuit board 51. In other words, the vibration damping device 1 can be configured, based on the parameters mentioned in the previous embodiments, to match the natural frequency of the circuit board 51, thereby effectively absorbing and reducing the vibrations caused by resonance.

In some other embodiments, the vibration damping device 1 may be mounted nearby components sensitive to vibrations; for example, the components may be integrated circuits (ICs), passive elements, sensors, quartz crystal oscillators, optical elements, or the like. Therefore, the vibration levels of the components can be reduced. In some other embodiments, the vibration damping device 1 may be mounted at the edge of the circuit board 51 or adjacent to the supporting portions of the circuit board 51 (because these portions are usually the stress concentration points), so that the vibration energy transmitted to the circuit board 51 can be reduced.

According to some embodiments of the instant disclosure, the vibration damping device 1 at least has following strengths. The vibration damping performance can be achieved using the flexible member 3 without relying external power source or complicated mechanical structure, thereby improving the durability and operation stability of the electronic apparatus 5. Since the damping device 1 is designed with a contactless structure, internal parts do not experience wear during operation, which extends the service life of the vibration damping device 1. Additionally, the flexible component 3 can be made of high-rigidity metal materials, which have excellent fatigue resistance, preventing elastic fatigue and maintaining stable damping effects even after long-term operation. Moreover, the vibration damping device 1 effectively absorbs and reduces vibrational shocks, ensuring that precision components remain stable during operation, avoiding performance degradation or structural damage caused by vibrations. Furthermore, since the vibration damping device 1 does not rely on additional driving mechanical structures and contains no components that generate friction, it produces virtually no noise during operation, providing a quiet operational environment for the electronic apparatus 5, which is suitable for noise-sensitive environments.

While the instant disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A vibration damping device comprising:
a fixed base;
a flexible member arranged on the fixed base, wherein the flexible member comprises at least one damping arm having at least one concave notch; and
a mass block disposed on the at least one damping arm;
wherein a ratio of a stiffness of the flexible member to a mass of the mass block is between 1.5×10⁶ to 4×10⁷.

2. The vibration damping device according to claim 1, wherein the at least one concave notch is selected from the group consisting of a semicircle groove, an ellipse groove, a rounded rectangle groove, a stadium-shaped groove, and a geometric polygon groove.

3. The vibration damping device according to claim 1, wherein the at least one damping arm comprises a plurality of the concave notches, and the concave notches are arranged on two opposing surfaces of the at least one damping arm.

4. The vibration damping device according to claim 3, wherein each of the concave notches is semicircle groove; for each of the semicircle grooves, a length of the semicircle groove is greater than a radius of the semicircle groove, and the radius of the semicircle groove is greater than a thickness between two semicircle grooves at the two opposing surfaces of the at least one damping arm.

5. The vibration damping device according to claim 1, wherein the flexible member comprises a plurality of the damping arms, and the flexible member has a centroid; by taking the centroid of the flexible member as a center of circle, central angles formed between each pair of adjacent damping arms among the plurality of damping arms are equal.

6. The vibration damping device according to claim 5, wherein a number of the damping arms is two, each of the two damping arms has a centroid, the two damping arms are orthogonal to each other, and the centroid of the two damping arms are coinciding with each other.

7. The vibration damping device according to claim 5, wherein the damping arms comprise an overlapped region and a plurality of fixed regions, the fixed regions are configured to be connected to the fixed base; the damping arms comprise a plurality of the concave notches, the concave notches are arranged on two opposing surfaces of the damping arms, and the concave notches are adjacent to the overlapped region and the fixed regions.

8. The vibration damping device according to claim 7, wherein the mass block is assembled on the overlapped region; in response to an operation of the vibration damping device, the mass block generates an amplitude along a first direction; notch directions of the concave notches are oriented in a direction aligned with the first direction.

9. The vibration damping device according to claim 1, wherein the fixed base comprises a hollow cylindrical body, an upper cover, and a lower base; the at least one damping arm spans across the hollow cylindrical body, the mass block is accommodated in the hollow cylindrical body; the upper cover and the lower base are respectively at two end openings of the hollow cylindrical body.

10. The vibration damping device according to claim 9, wherein each of the at least one damping arm and the mass block has a centroid, the centroid of the at least one damping arm and the centroid of the mass block are on a centerline of the hollow cylindrical body.

11. The vibration damping device according to claim 9, wherein the hollow cylindrical body comprises a first opening end and a second opening end; the upper cover is assembled on the first opening end, and the lower base is assembled on the second opening end; the first opening end of the hollow cylindrical body further comprises a plurality of mounting slots, and two ends of the at least one damping arm are respectively mounted on the mounting slots.

12. The vibration damping device according to claim 11, wherein the lower base comprises an axial projection and a radial flange, the axial projection is in the hollow cylindrical body, and the radial flange radially extends from the second end opening of the hollow cylindrical body.

13. The vibration damping device according to claim 1, wherein in response to a vibration frequency between 200 Hz and 1000 Hz, the vibration damping device damps 20% or more of a vibration level.

14. The vibration damping device according to claim 1, wherein the flexible member is made of metallic material, and the stiffness of the flexible member is equal to or greater than 60 GPa.

15. An electronic apparatus comprising:
a circuit board; and
a vibration damping device mounted on the circuit board, wherein the vibration damping device comprises:
a fixed base;
a flexible member arranged on the fixed base, wherein the flexible member comprises at least one damping arm having at least one concave notch; and
a mass block disposed on the at least one damping arm;
wherein a ratio of a stiffness of the flexible member to a mass of the mass block is between 1.5×10⁶ to 4×10⁷.

16. The electronic apparatus according to claim 15, wherein the fixed base comprises a hollow cylindrical body, an upper cover, and a lower base; the hollow cylindrical body comprises a first opening end and a second opening end; the upper cover is assembled on the first opening end, and the lower base is assembled on the second opening end; the first opening end of the hollow cylindrical body further comprises a plurality of mounting slots, and two ends of the at least one damping arm are respectively mounted on the mounting slots.

17. The electronic apparatus according to claim 16, wherein the lower base comprises an axial projection and a radial flange, the axial projection is in the hollow cylindrical body, the radial flange extends along a radial direction from the second end opening of the hollow cylindrical body, and the radial flange is configured to be assembled on the circuit board.

18. The electronic apparatus according to claim 15, wherein a number of the at least one damping arm is two, each of the two damping arms has a centroid, the two damping arms are orthogonal to each other, and the centroid of the two damping arms are coinciding with each other.

19. The electronic apparatus according to claim 18, wherein the two damping arms comprise an overlapped region and a plurality of fixed regions, the fixed regions are configured to be connected to the fixed base; the two damping arms comprise a plurality of the concave notches, the concave notches are arranged on two opposing surfaces of the two damping arms, and the concave notches are adjacent to the overlapped region and the fixed regions.

20. The electronic apparatus according to claim 19, wherein the mass block is assembled on the overlapped region; in response to an operation of the vibration damping device, the mass block generates an amplitude along a first direction; notch directions of the concave notches are oriented in a direction aligned with the first direction.
